(19) United States
(12) Patent Application Publication
(10) Pub. No.: US 2013/0099371 A1
(43) Pub. Date: Apr. 25, 2013

(54) SEMICONDUCTOR PACKAGE HAVING SOLDER JOINTED REGION WITH CONTROLLED AG CONTENT

(71) Applicants: Ming-Da CHENG, Jhubei City (TW); Kuei-Wei HUANG, Hsinchu City (TW); Yu-Peng TSAI, Taipei City (TW); Cheng-Ting CHEN, Taichung City (TW); Hsiu-Jen LIN, Zhubei City (TW); Chung-Shi LIU, Hsinchu City (TW)

(72) Inventors: Ming-Da CHENG, Jhubei City (TW); Kuei-Wei HUANG, Hsinchu City (TW); Yu-Peng TSAI, Taipei City (TW); Cheng-Ting CHEN, Taichung City (TW); Hsiu-Jen LIN, Zhubei City (TW); Chung-Shi LIU, Hsinchu City (TW)

(73) Assignee: TAIWAN SEMICONDUCTOR MANUFACTURING COMPANY, LTD., Hsinchu (TW)

(21) Appl. No.: 13/278,621

(22) Filed: Oct. 21, 2011

(51) Int. Cl. H01L 23/498; H01L 21/60

(52) U.S. Cl. 257/737; 438/125; 257/E23.068; 257/E21.511

(57) ABSTRACT

A semiconductor package includes a workpiece with a conductive trace and a chip with a conductive pillar. The chip is attached to the workpiece and a solder joint region is formed between the conductive pillar and the conductive trace. The silver (Ag) content in the solder layer is between 0.5 and 1.8 weight percent.

### BACKGROUND

Integrated circuit chips include semiconductor devices formed on a substrate such as a semiconductor wafer and include metalized contact pads for providing an electrical interface to the integrated circuitry. Bonding bumps are part of the interconnecting structure in an integrated circuitry. A bump provides an interface to an integrated circuit device through which an electrical connection to the device may be made. Techniques for providing a connection between the internal circuitry of a chip and external circuitry, such as a circuit board, another chip, or a wafer, include wire bonding, in which wires are used to connect the chip contact pads to the external circuitry, and may also include other techniques known in the art. A more recent chip connection technique, known as flip chip technology, provides for connection of integrated circuit devices to external circuitry using solder bumps that have been deposited onto the chip contact pads. In order to mount the chip to external circuitry, the chip is flipped over so that its topside faces down and its contact pads are aligned with matching contact pads on the external circuit. The solder is then reflowed between the flipped chip and the substrate supporting the external circuitry to complete the interconnection. The resulting flip chip package is much smaller than a traditional carrier-based system, because the chip is positioned directly on the external circuitry, such that the interconnect wires may be much shorter. As a result, the inductance and resistive heat are greatly reduced, enabling higher-speed devices.

### BRIEF DESCRIPTION OF THE DRAWINGS

FIG. 1 and FIG. 2 are cross-sectional views of intermediate stages in the manufacturing of a semiconductor device in accordance with an embodiment;

FIG. 3 are top views of three exemplary elongated bump structures according to some embodiments of the present disclosure;

FIG. 4 is a cross-sectional view of a workpiece in accordance with an embodiment;

FIG. 5 is a cross-sectional view of a semiconductor package comprising a chip coupled to a workpiece in an embodiment;

FIG. 6 are top views of three exemplary elongated bump-on-trace interconnect structures according to an embodiment of the present disclosure; and

FIG. 7 is a flow chart of a method for forming a semiconductor package according to an embodiment of the present disclosure.

### DETAILED DESCRIPTION

Reference will now be made in detail to exemplary embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, apparatus in accordance with the present disclosure. It is to be understood that elements not specifically shown or described may take various forms well known to those skilled in the art. Further, when a layer is referred to as being on another layer or “on” a substrate, it may be directly on the other layer or on the substrate, or intervening layers may also be present.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

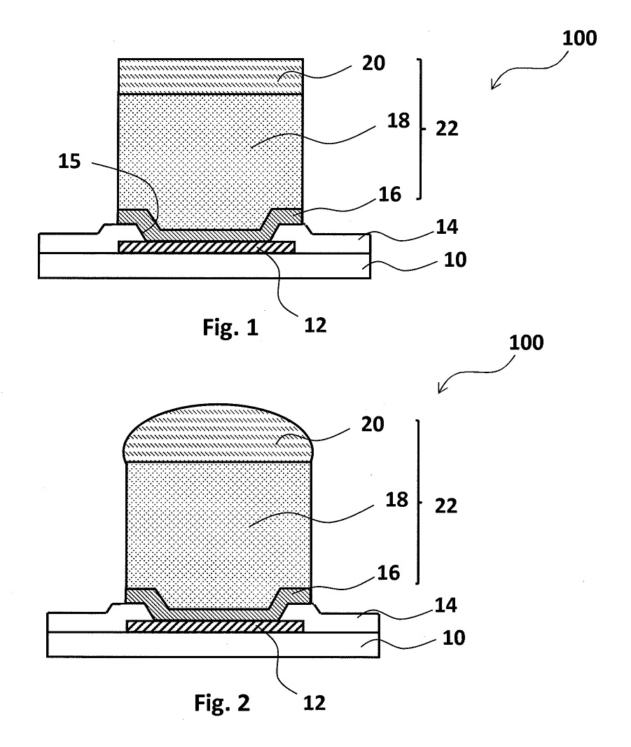

FIGS. 1 and 2 are cross-sectional views of a portion of a semiconductor device at various stages in an integrated circuit manufacturing process in an embodiment.

Referring to FIG. 1, a portion of a chip 100 having electrical circuitry formed in and/or upon a semiconductor substrate 10 is shown. The semiconductor substrate 10 comprises one of a variety of types of semiconductor substrates commonly employed in semiconductor integrated circuit fabrication, and integrated circuits may be formed therein and/or thereupon. In an embodiment, the semiconductor substrate comprises semiconductor materials, including but not limited to, bulk silicon, a semiconductor wafer, a silicon-on-insulator (SOI) substrate, or a silicon germanium substrate. In other embodiments, the semiconductor substrate comprises other semiconductor materials, including group III, group IV, and/or group V semiconductors. Although not shown, it will be recognized that the substrate 10 may further comprise a plurality of isolation features, such as shallow trench isolation (STI) features or local oxidation of silicon (LOCOS) features. The isolation features isolate various microelectronic elements formed in and/or upon the substrate 10. Examples of the types of microelectronic elements formed in the substrate 10 include, but are not limited to, transistors such as metal oxide semiconductor field effect transistors (MOSFETs), complementary metal oxide semiconductor (CMOS) transistors, bipolar junction transistors (BJTs), high voltage transistors, high frequency transistors, p-channel and/or n-channel field effect transistors (PFETs/NFETs), resistors, diodes, capacitors, inductors, fuses, and/or other suitable elements. Various processes are performed to form the various microelectronic elements, including but not limited to one or more of deposition, etching, implantation, photolithography, annealing, and other suitable processes. The microelectronic elements are interconnected to form the integrated circuit device, which comprise one or more of a logic device, memory device (e.g., SRAM), radio frequency (RF) device, input/output (I/O) device, system-on-chip (SoC) device, and other suitable types of devices. The substrate 10 further comprises an interconnection structure overlying the integrated circuits. The interconnection structure includes inter-layer dielectric layers and a metallization structure overlying the integrated circuits. The inter-layer dielectric layers in the metallization structure comprise one or more of low-k dielectric materials, un-doped silicate glass (USG), silicon nitride (SiN), silicon oxynitride (SiON), and other commonly used materials. The dielectric constants (k value) of the low-k dielectric materials may be less than about 3.9, or less than about 2.8. Metal lines in the metallization structure comprise copper, copper alloys or other suitable materials known in the art.

Conductive pads 12 are formed and patterned in or on a top-level inter-layer dielectric layer. In an embodiment, the conductive pad 12 is a portion of conductive routes. In one embodiment, the conductive pads 12 comprise contact pads for providing an electrical connection upon which a bump structure, such as a UBM structure, a solder bump or a copper pillar bump, may be formed for facilitating external electrical connections. The conductive pads 12 comprise any suitable conductive materials, including one or more of copper (Cu), tungsten (W), aluminum (Al), AlCu alloys, silver (Ag), or similar materials, for example. In an embodiment, the conductive pads 12 may be a region or an end of a redistribution line to provide the desired pin or ball layout.

In an embodiment, one or more passivation layers, such as a passivation layer 14, are formed and patterned over the conductive pads 12. In one embodiment, an opening 15 is provided in the passivation layer 14, exposing an underlying portion of the conductive pad 12. In an embodiment, the passivation layer 14 is formed of a non-organic material, such as un-doped silicate glass (USG), silicon nitride, silicon oxynitride, silicon oxide, or combinations thereof. The passivation layer 14 may be formed by any suitable method, such as chemical vapor deposition (CVD), physical vapor deposition (PVD), or the like. In other embodiments, the passivation layer 14 comprises a polymer layer, such as an epoxy, polyimide, benzocyclobutene (BCB), polybenzoxazole (PBO), or the like, although other relatively soft, often organic, dielectric materials can also be used. One of ordinary skill in the art will appreciate that a single pad layer and a single passivation layer are shown for illustrative purposes only. As such, one embodiment comprises any number of conductive pads and/or passivation layers.

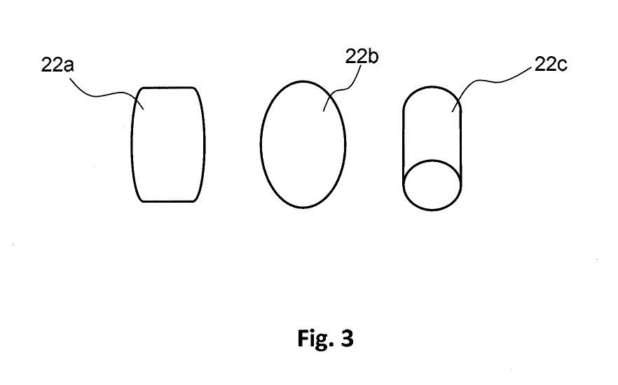

FIG. 1 also illustrates a bump structure 22 formed on the passivation layer 14 and electrically connected to the conductive pad 12 through the opening 15. The bump structure 22 includes an under-bump-metallurgy (UBM) layer 16, a conductive pillar 18 formed on the UBM layer 16 and a solder layer 20 formed on the conductive pillar 18. In an embodiment, the top view of the UBM layer 16 and/or the conductive pillar 18 of the bump structure 22 is an elongated shape. Various shapes may be used to implement the elongated bump structure, including, but not limited to, a rectangle, a rectangle with at least one curved or rounded side, a rectangle with two convex curved sides, an oval, an ellipse or any other elongated shape. In other embodiments, the top view of the bump structure 22 is circular, octagonal, or the like. Referring now to FIG. 3, illustrated are top views of three exemplary elongated bump structures. An elongated structure 22a shows rectangular with two convex curved long-sides. An elongated structure 22b shows an ellipse-shaped bump structure. Similarly, an elongated structure 22c shows a rectangular with two convex curved short-sides.

The UBM layer 16 is formed on the exposed portion of the conductive pad 12. The UBM layer 16 may extend onto the passivation layer 14. In one embodiment, the UBM layer 16 includes a diffusion barrier layer or a glue layer, which comprises titanium (Ti), tantalum (Ta), titanium nitride (TiN), tantalum nitride (TaN), or the like and is formed by PVD or sputtering. In other embodiments, the UBM layer 16 further comprises a seed layer formed on the diffusion barrier layer by PVD or sputtering. In one embodiment, the seed layer comprises copper (Cu) or copper alloys including Al, chromium (Cr), nickel (Ni), tin (Sn), gold (Au), or combinations thereof. In one embodiment, the UBM layer 16 comprises a Ti layer and a Cu seed layer.

The conductive pillar 18 is formed on the UBM layer 16. In one embodiment, the conductive pillar 18 comprises a Cu layer. The Cu layer comprises pure elemental copper, copper containing unavoidable impurities, and/or copper alloys containing minor amounts of elements such as Ta, indium (In), SN, zinc (Zn), manganese (Mn), Cr, Ti, germanium (Ge), strontium (Sr), platinum (Pt), magnesium (Mg), aluminum (Al) or zirconium (Zr). In one embodiment, the conductive pillar 18 is formed by sputtering, printing, electroplating, electro-less plating, electrochemical deposition (ECD), molecular beam epitaxy (MBE), atomic layer deposition (ALD), and/or commonly used CVD methods. In other embodiments, the Cu layer is formed by electro-chemical plating (ECP). In an embodiment, the thickness of the conductive pillar 18 is greater than 20 μm. In other embodiments, the thickness of the conductive pillar 18 is greater than 40 μm. For example, the conductive pillar 18 is of about 20˜50 μm thickness, or about 40˜70 μm thickness, although the thickness may be greater or smaller.

The solder layer 20 is formed on the conductive pillar 18. In one embodiment, the solder layer 20 is a lead-free solder layer. In one embodiment, the solder layer 20 is formed by plating process. For a lead-free solder system, the solder layer 20 is SnAg with Ag content being controlled at a range between about 0.5 weight percent (wt %) and about 1.8 wt %. In one embodiment, the Ag content in the solder layer 20 is at the range between about 0.5 wt % to about 1.0 wt %. In other embodiments, the Ag content in the lead-free solder layer 20 is at the range between about 1.1 wt % to about 1.5 wt %. In still other embodiments, the Ag content in the lead-free solder layer 20 is at the range between about 1.5 wt % to about 1.8 wt %. In an embodiment, a reflow process can be performed on the solder layer 20, thus the solder layer 20 becomes a reflowed solder layer with a spherical surface as shown in FIG. 2.

After completing the bump structure 22, the chip 100 will be attached to a substrate, such as a dielectric substrate, a package substrate, a printed circuit board (PCB), an interposer, a wafer, another chip, a package unit, or the like. For example, embodiments may be used in chip-to-substrate bonding configuration, a chip-to-chip bonding configuration, a chip-to-wafer bonding configuration, a wafer-to-wafer bonding configuration, chip-level packaging, wafer-level packaging, or the like. In an embodiment, the bump structure 22 is connected to a metal trace on the substrate, thus a bump-on-trace (BOT) interconnect is formed in a semiconductor package.

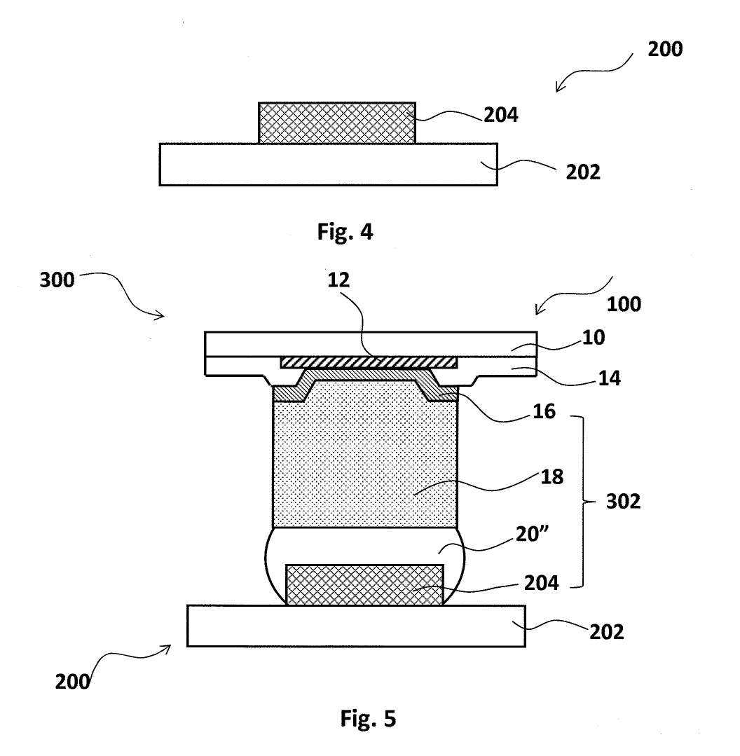

FIG. 4 is a cross-sectional view of a workpiece in an embodiment. FIG. 5 is a cross-sectional view of a semiconductor package comprising a chip 100 coupled to a workpiece 200 in an embodiment.

Referring to FIG. 4, a workpiece 200 includes a substrate 202, which comprises a package substrate, a PCB, a wafer, a chip, an interposer, a dielectric substrate, a package unit or other suitable substrate. The substrate 202 comprises a plurality of conductive traces 204 electrically connected to underlying metal interconnection. In an embodiment, the conductive traces 204 comprise substantially pure Cu, AlCu, or other metallic materials such as W, Ni, Pd, Au, and alloys thereof. Some areas of the conductive traces 204 are defined as landing regions for electrically connecting to the bump structures 22. In one embodiment, there is no solder layer formed on the landing region of the conductive trace 204. In an embodiment, the landing regions of the conductive traces are defined by a non-solder mask defined (NSMD) type. In other embodiments, the landing regions of the conductive traces are defined by a solder mask define type.

Referring to FIG. 5, the chip 100 with the bump structure, as shown in FIGS. 1 and 2, is flipped upside down and attached to the workpiece 200 through flip-chip bonding technologies so as to form a semiconductor package 300. In an embodiment, an exemplary coupling process comprises a thermal process, such as reflowing or thermal compression bonding, performed to melt the solder layer. The melted solder material thus joins the chip 100 and the workpiece 200 together and electrically connects the bump structure 22 to the conductive trace 204. A solder joint region 20″ formed by melting the solder material is therefore formed between the conductive pillar 18 and the conductive trace 204. The bump structure, as shown in FIGS. 1 and 2, is electrically connected to the conductive trace 204 through the solder joint region 20b forming a bump-on-trace (BOT) interconnect structure 302 in the semiconductor package 300. In an embodiment, after forming the BOT interconnect structure, an underfill (not shown) is filled into the space between chip 100 and workpiece 200, and thus the underfill is also filled into the space between neighboring conductive traces. In other embodiments, no underfill is provided in the semiconductor package 300.

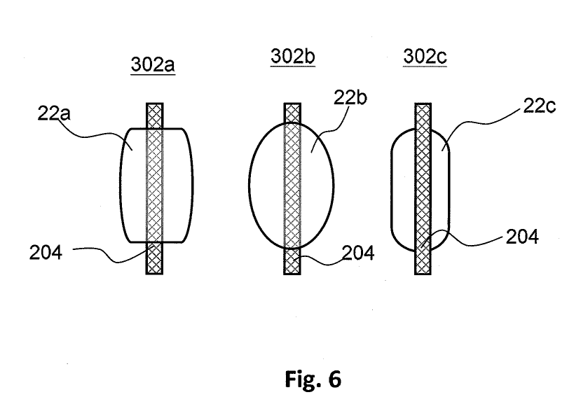

Referring now to FIG. 6, illustrated are top views of three exemplary BOT interconnect structures 302a, 302b and 302c. Structure 302a comprises an elongated bump structure 22a formed on the conductive trace 204, the bump shaped as a rectangular with two convex curved long-sides. Structure 302b comprises an ellipse-shaped bump structure 22b formed over trace 204. Similarly, structure 302c comprises an elongated shaped bump 22c formed over the conductive trace 204, the bump shaped as a rectangular with two convex curved short-sides. In an embodiment, the elongated axis of the elongated bump structure runs coaxial, i.e., parallel or nearly parallel to the axis of the conductive trace 204.

In the solder joint region 20″, the Ag content is substantially the same as in the solder layer 20. In one embodiment, in the solder joint region 20″, the Ag content is well controlled at a range between about 0.5 wt % and about 1.8 wt %. In other embodiments, the Ag content in the solder joint region 20″ is at the range between about 0.5 wt % to about 1.0 wt %. In still other embodiments, the Ag content in the solder joint region 20″ is at the range between about 1.1 wt % to about 1.5 wt %. In alternative embodiments, the Ag content in the solder joint region 20″ is at the range between about 1.5 wt % to about 1.8 wt %. Reliability of package using lead-free solder alloy relates to several factors, including bump hardness and formation of inter-metallic compounds (IMCs) and voids, which potentially contribute to crack formation and cause thermo-mechanical stresses on the solder joint. Applicants learned the Ag content in the solder joint region controlled at the range between about 0.5 wt % and about 1.8 wt % can prevent electromigration failure and avoid large Ag₃Sn growth, thereby improving package reliability. Compared with the solder joint region having a higher Ag content at a range more than 3 wt %, the embodiments of the present disclosure provide a semiconductor package having a solder joint with a lower Ag content being controlled less than 1.8 wt %, which reduces process costs and overcome crack issues to solve the yield loss problem.

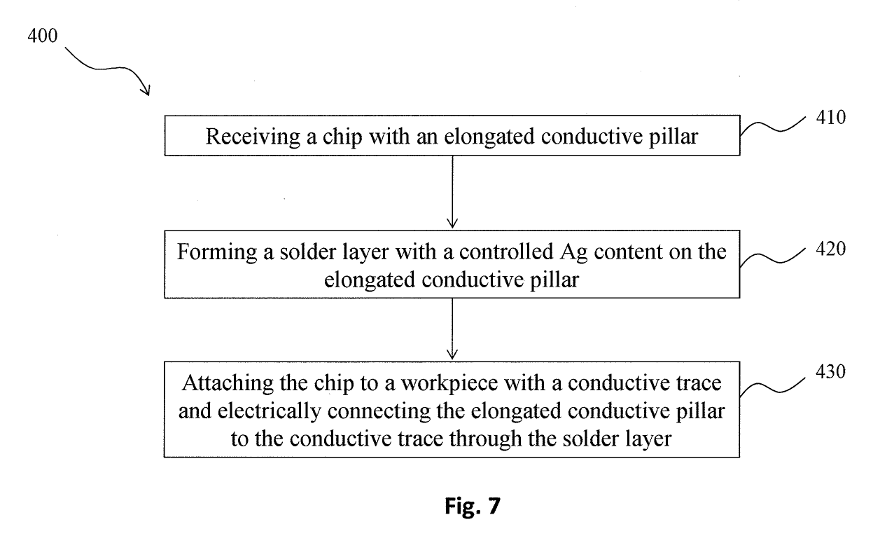

FIG. 7 is a flow chart of the method for fabricating a semiconductor package according an embodiment of the present disclosure. The method 400 begins with step 410 in which a chip with an elongated conductive pillar is provided. In an embodiment, the conductive pillar comprises copper or copper alloys. In an embodiment, the conductive pillar is an elongated shape. The method 400 continues with step 420 in which a solder layer with a controlled Ag content is formed on the elongated conductive pillar. In an embodiment, the solder layer is a lead-free solder, and the solder layer is SnAg with Ag content being controlled at a range between about 0.5 weight percent (wt %) and about 1.8 wt %. In other embodiments, the Ag content in the solder layer is at the range between about 0.5 wt % to about 1.0 wt %. In still other embodiments, the Ag content in the lead-free solder layer is at the range between about 1.1 wt % to about 1.5 wt %. In alternative embodiments, the Ag content in the lead-free solder layer is at the range between about 1.5 wt % to about 1.8 wt %. The method 400 continues with step 430 in which the chip is attached to a workpiece with a conductive trace and the elongated conductive pillar is electrically connected to the conductive trace through the solder layer. A bump-on-trace (BOT) interconnect structure is therefore formed in a semiconductor package. In an embodiment, the workpiece is a dielectric substrate and the conductive trace comprises copper or copper alloys. In one embodiment, the solder joint region includes the Ag content at a range between about 0.5 weight percent (wt %) and about 1.8 wt %. In other embodiments, the Ag content in the solder joint region is at the range between about 0.5 wt % to about 1.0 wt %. In still other embodiments, the Ag content in the solder joint region is at the range between about 1.1 wt % to about 1.5 wt %. In alternative embodiments, the Ag content in the solder joint region is at the range between about 1.5 wt % to about 1.8 wt %.

In an embodiment of the disclosure, a semiconductor package comprises a workpiece with a conductive trace and a chip with a conductive pillar. The chip is attached to the workpiece and a solder joint region is formed between the conductive pillar and the conductive trace. The silver (Ag) content in the solder layer is at a range between 0.5 weight percent (wt %) and 1.8 wt %.

In an embodiment of the disclosure, a semiconductor package comprises a workpiece with a conductive trace and a chip with a bump structure. The chip is attached to the workpiece and the bump structure is jointed to the conductive trace to form a bump-on-trace (BOT) interconnect. The BOT interconnect comprises a solder joint region, and the silver (Ag) content in the solder layer is not greater than 1.8 weight percent (wt %).

In an embodiment of the disclosure, a method includes receiving a semiconductor substrate with an elongated conductive pillar, forming a solder layer on the elongated conductive pillar, and attaching the semiconductor substrate to a dielectric substrate with a conductive trace. The conductive pillar is therefore electrically connected to the conductive trace through the solder layer. The silver (Ag) content in the solder layer is not greater than 1.8 weight percent (wt %).

In the preceding detailed description, the disclosure is described with reference to specific exemplary embodiments thereof. It will, however, be evident that various modifications, structures, processes, and changes may be made thereto without departing from the broader spirit and scope of the disclosure. The specification and drawings are, accordingly, to be regarded as illustrative and not restrictive. It is understood that the disclosure is capable of using various other combinations and environments and is capable of changes or modifications within the scope of inventive concepts as expressed herein.

What is claimed is:

1. A semiconductor package, comprising:
a workpiece comprising a conductive trace; and
a chip comprising a bump structure,
wherein the chip is attached to the workpiece and the bump structure is electrically connected to the conductive trace to form a bump-on-trace (BOT) interconnect structure; and
wherein the BOT interconnect structure comprises a solder region, and a silver (Ag) content in the solder region is not greater than 1.8 weight percent.

2. The semiconductor package of claim 1, wherein the Ag content in the solder region is between 0.5 and 1.8 weight percent.

3. The semiconductor package of claim 1, wherein the Ag content in the solder region is between 0.5 and 1.0 weight percent.

4. The semiconductor package of claim 1, wherein the Ag content in the solder region is between 1.1 and 1.5 weight percent.

5. The semiconductor package of claim 1, wherein bump structure is an elongated shape.

6. The semiconductor package of claim 1, wherein the bump structure comprises a conductive pillar.

7. The semiconductor package of claim 6, wherein the conductive pillar comprises copper.

8. The semiconductor package of claim 1, wherein the workpiece comprises a dielectric substrate and the conductive trace comprises copper.

9. The semiconductor package of claim 1, wherein the solder region is free of lead (Pb).

10. A semiconductor package, comprising:
a workpiece comprising a conductive trace; and
a chip comprising a conductive pillar and a solder layer on the conductive pillar,
wherein the chip is attached to the workpiece and the conductive pillar is electrically connected to the conductive trace through the solder layer,
wherein a silver (Ag) content in the solder layer is between 0.5 and 1.8 weight percent.

11. The semiconductor package of claim 10, wherein the Ag content in the solder layer is between 0.5 and 1.0 weight percent.

12. The semiconductor package of claim 10, wherein the Ag content in the solder layer is between 0.5 and 1.5 weight percent.

13. The semiconductor package of claim 10, wherein the Ag content in the solder layer is between 1.5 and 1.8 weight percent.

14. The semiconductor package of claim 10, wherein the conductive pillar is an elongated shape.

15. The semiconductor package of claim 10, wherein the conductive pillar comprises copper.

16. The semiconductor package of claim 10, wherein the solder layer is free of lead (Pb).

17. A method, comprising:
receiving a semiconductor substrate comprising an elongated conductive pillar;
forming a solder layer on the elongated conductive pillar, wherein a silver (Ag) content in the solder layer is between 0.5 and 1.8 weight percent;
receiving a dielectric substrate comprising a conductive trace; and
attaching the semiconductor substrate to the dielectric substrate and electrically connecting the elongate conductive pillar to the conductive trace through the solder layer.

18. The method of claim 17, wherein the elongated conductive pillar is a rectangular shape comprising a curved side.

19. The method of claim 17, wherein the solder layer is free of lead (Pb).

20. The method of claim 17, further comprising performing a reflow process on the solder layer.
